(19) United States
(12) Patent Application Publication
(10) Pub. No.: US 2007/0137701 A1
(43) Pub. Date: Jun. 21, 2007

(54) Device comprising at least one type of tubular nanostructure having at least one complex pigment on the surface thereof

(75) Inventors: Julien Sainte Catherine, Perols (FR); Jerome Fraysse, Chalons-En-Champagne (FR)

Correspondence Address: LE-NHUNG MCLELAND, 9679-C MAIN STREET, FAIRFAX, VA, 22031-3766, US

(73) Assignee: Nanoledge, Clapiers (FR)

(21) Appl. No.: 10/560,110

(22) PCT Filed: Jun. 10, 2004
(86) PCT No.: PCT/FR04/01444

§ 371 Date: Jul. 28, 2006

(30) Foreign Application Priority Data
Jun. 11, 2003 (FR) 0306977

(51) Int. Cl. H01L 31/00

(52) U.S. Cl. 136/263; 977/748; 977/948

(57) ABSTRACT

The present invention relates to a device comprising at least one type of conjugated polymer and at least one type of particular tubular nanostructure. The invention relates mainly to a device comprising at least one type of conjugated polymer (functioning as an electron donor) and at least one type of tubular nanostructure (functioning as an electron acceptor), said tubular nanostructure comprising at least one complexed pigment on its surface. The device is proposed in particular for forming a photovoltaic cell.

Device comprising at least one type of tubular nanostructure having at least one complex pigment on the surface thereof

The invention relates to carbon nanotubes, to dispersions of these nanotubes, to composite materials and to articles made of a composite material comprising these carbon nanotubes. It further relates to the processes for the manufacture of such products.

The present invention further relates to a device comprising at least one type of conjugated polymer and at least one type of particular tubular nanostructure. Different devices are proposed for forming a photovoltaic cell.

### STATE OF THE ART

Since their discovery in 1991 (Iijima, S., Nature 354 (1991) 56-58), carbon nanotubes have quickly aroused the interest of researchers due to their unique properties. Their exceptional elasticity and tensile strength, their very good electrical and thermal conductivities and their chemical and thermal stabilities open up numerous potential implications for nanotubes in sectors as diverse as electronics, medicine or aeronautics.

The properties of carbon nanotubes have been described fairly exhaustively in the past (R. Saito, G. Dresselhaus, M. S. Dresselhaus, “Physical Properties of Carbon Nanotubes”, Imperial College Press, London UK 1998; J.-B. Donnet, T. K. Wang, J. C. M. Peng, S. Rebouillat [ed.], “Carbon Fibers”, Marcel Dekker NY, USA 1998).

Single-wall carbon nanotubes (SWNT) are generally synthesized by physical methods (electric arc or laser), whereas multi-wall carbon nanotubes (MWNT) are produced by a chemical method comprising the decomposition of hydrocarbon gases.

The diameter of the nanotubes varies from about 0.4 nm to more than 3 nm for the SWNT and from about 1.4 nm to at least 100 nm for the MWNT (Z. K. Tang et al., Science 292, 2462 (2001); R. G. Ding, G. Q. Lu, Z. F. Yan, M. A. Wilson, J. Nanosci. Nanotechnol. 1, 7 (2001)).

Some studies have also demonstrated that the incorporation of carbon nanotubes into solid plastics makes it possible to improve the mechanical and electrical properties of these solid plastics (M. J. Biercuk et al., Appl. Phys. Lett. 80, 2767 (2002); D. Qian, E. C. Dickey, R. Andrews, T. Randell, Appl. Phys. Lett. 76, 2868 (2000)).

The properties of carbon nanotubes enable them to be used for electron emitters, membranes or tips for atomic force microscopy.

Furthermore, nanotubes can contribute to avoiding local electrostatic charging, as observed during the application of powder paint to a metal or plastic surface.

To enable the favorable properties of carbon nanotubes to be imparted to the solid material to which they are added, the nanotubes have to be distributed homogeneously in the constituent matrix of the material. To do this, it is first necessary to prepare dispersions of carbon nanotubes in a liquid medium. For such dispersions to be stable, i.e. for there to be no aggregation or precipitation of the nanotubes in the liquid medium, the adhesive forces between the particles must be minimized. In fact, both SWNT and MWNT tend to assemble in the form of bundles containing. several nanotubes.

For this purpose, patent application WO 02/076888 A1 describes suspensions of carbon nanotubes in a liquid medium containing up to 65% by weight of carbon tubes coated with polymers. However, these suspensions are only suspensions either in pure water or in aqueous solutions.

Now, to manufacture composite materials containing nanotubes, in particular, it is necessary to obtain dispersions of nanotubes in liquid organic solvents that are insoluble in or immiscible with water.

U.S. Pat. No. 6,099,965 describes such suspensions in organic solvents, optionally in the presence of a dispersant, but the concentration of carbon nanotubes in these suspensions in an organic liquid medium does not exceed 0.1% by weight.

U.S. Pat. No. 6,187,823 B1 describes solutions of carbon nanotubes in an organic solvent. However, on the one hand the carbon nanotubes are Single-wall nanotubes which have been modified by the attachment of an amine or an alkylarylamine to their surface, and on the other hand the intrinsic properties of the nanotubes are degraded due to their chemical modification on the surface and the destruction of carbon-carbon bonds by the grafting of amine groups onto the structure.

In summary, methods currently exist for dispersing nanotubes in aqueous solvents at concentrations greater than 10%, but no method exists for dispersing amounts greater than 0.1% by weight in organic solvents that are insoluble in or immiscible with water, without chemically modifying the nanotubes.

The fact that it is currently impossible to disperse such amounts of nanotubes in organic solvents that are insoluble in or immiscible with water, and hence to integrate these nanotubes homogeneously into an organic matrix that is immiscible with or insoluble in water, constitutes an obstacle to the use of carbon nanotubes as a filler.

In another connection, photovoltaic cells (also called solar cells) are one of the most valuable ecological means of energy conversion to have appeared in past decades. Considerable effort has been dedicated to the development of solar cells. These cells are now used as components of widely distributed electronic products such as pocket calculators. Although significant advances have been made in the development of photovoltaic cells, it is still necessary to improve their energy conversion efficiency, extend their life and reduce their cost in order to open up other markets such as the telecommunications, automobile or home automation market.

A consequent state of the art exists for photovoltaic cells based on conventional semiconductor materials such as silicon, gallium arsenide, cadmium sulfide, etc. In these devices, which include a PN heterojunction, the production of electric current is based on photon-induced dissociation of the charges at the junction. Production of the semiconductor materials used in these devices requires high manufacturing temperatures, and the photovoltaic cells only achieve optimum performance characteristics when monocrystalline materials are used. These technological constraints directly or indirectly increase the production costs and play a major part in reducing the field of applications of photovoltaic cells based on semiconductor materials.

The possibility of using conjugated polymers as active elements (electron donor structure) of photovoltaic cells has been demonstrated since the beginning of the 1980's (Proprietes photovoltaïques des polymères conjugués (Photovoltaic properties of conjugated polymers): B. R. Weinberger, S. C. Gau and Z. Kiss, Appl. Phys. Lett. 38, 555 (1981); R. N. Marks, J. J. M. Halls, D. D. C. Bradley, R. H. Friend and A. B. Holmes, J. Phys.: Condens. Matter 6, 1379 (1994)).

In organic materials the absorption of photons creates excited states and generates electron-hole pairs: excitons. In this case the production of electric current requires dissociation of the excitons followed by transport of the charges to the opposite electrodes. The use of conjugated polymers can have important advantages. For example, it allows a choice to be made regarding the width of the forbidden energy band of the polymer (either by a judicious choice of the conjugated skeleton or by functionalizations of branched chains) and could thus make it possible to adjust the absorption spectrum of the polymer to that of the solar spectrum. The ease of use of polymers, particularly soluble conjugated polymers, makes it possible to manufacture devices of very large surface area, and important cost reductions would be made in comparison with the existing technologies. Nevertheless, these systems suffer from a lower efficiency and a shorter life than the devices based on monocrystalline semiconductor materials.

Improvements to photovoltaic cells based on p-type conjugated polymers (i.e. those behaving as electron donors) have been proposed. For example, patents U.S. Pat. No. 5,454,880 and U.S. Pat. No. 5,986,206 respectively describe the incorporation of fullerenes and small carbon particles acting as electron acceptors. However, the devices described have the disadvantage of a limited dissipation of heat and a limited dissipation of charges (particularly electrons) to the outside of the cell, which degrades the conducting polymer, limits the life of the photovoltaic cells and restricts their efficacy.

However, the performance characteristics are restricted by the limited dissociation of excitons, the limited transport of charges to the electrodes and the limited dissipation of heat to the outside of the cell. All these disadvantages limit the present devices to low photoelectric efficiencies.

### OBJECTS OF THE INVENTION

In a first part, the aim of the invention is to overcome the disadvantages of the prior art by proposing to reduce the interparticulate interactions between the nanotubes by complexing them to give stable homogeneous dispersions with a high concentration of carbon nanotubes in water-immiscible organic media.

In a second part, the main object of the present invention is to solve the numerous above-mentioned technical problems concerning photovoltaic conversion, and especially the problem that consists in providing a device comprising at least one type of conjugated polymer (functioning as an electron donor structure) and at least one type of tubular nanostructure (functioning as an electron acceptor structure), the nanostructures comprising at least one complexed pigment on their surface, thereby making it possible to improve the efficiency and life of the cells.

Another object of the present invention is to provide processes for the manufacture of such devices so that they can be used as photovoltaic conversion elements, especially in photovoltaic cells.

The object of the present invention is to improve the performance characteristics, in terms of energy conversion efficacy and life, of photovoltaic devices based on conjugated polymers.

The present invention will also make it possible to broaden the field of applications of such devices by virtue of the low production costs of such cells compared with the other known methods.

Another object of the present invention is to improve the general performance characteristics of photovoltaic cells based on conjugated polymers.

The improvement in performance characteristics correlates particularly with effective dissociation of the excitons.

This involves the presence of a fairly large number of exciton dissociation centers. These centers are generally acceptor entities for electric charges (electrons or holes). The dissociation centers must be readily accessible to the excitons. This involves on the one hand a good intimacy between the donor entities (conjugated polymer chains and/or pigments) and the dissociation centers, and on the other hand a preferred size for the dissociation centers on the molecular scale to give a very large interface between these centers and the donor molecules. The object of the invention is to solve this technical problem.

There are two other crucial points apart from dissociation of the excitons:

There must be effective transport of charges to the electrodes. Once the excitons are dissociated, it is necessary to prevent their recombination and assure their rapid transport to the electrodes across separate phases.

Finally, the dissipation of heat to the outside of the cell must be assured. In fact, heat is capable on the one hand of modifying the characteristics of the cell (e.g. by changing the conformation of the polymer chains) and on the other hand of limiting the life of the cells by degrading the polymer chains. Heat dissipation is therefore a crucial aspect of the improvement of photovoltaic cells based on conjugated polymers.

Another object of the invention is to provide active elements of photovoltaic cells in a form which makes it possible to build photovoltaic cells in a variety of shapes and on supports having a variety of shapes.

### DESCRIPTION OF THE INVENTION

In a First Part:

In the context of the present invention the term “nanotube” denotes a carbon-based material such as straight and bent carbon nanofibers, straight and bent Single-wall, double-wall or multi-wall carbon nanotubes (SWNT, DWNT or MWNT), carbon fibers grown in the vapor phase (VGCF), and any cylindrical or tubular carbon structures. The expression “multi-wall nanotubes” will hereafter denote double-wall nanotubes as well as nanotubes consisting of three or more walls. The term “nanotube” also denotes a mixture of carbon nanotubes with one or more components such as amorphous carbon, graphite or a catalyst (form in which the nanotubes are found after production).

“Stable dispersions” are understood within the framework of the present invention as meaning dispersions that exhibit neither reaggregation nor re-precipitation of the carbon nanotubes in the dispersion after storage for at least four days at ambient temperature.

“Homogeneous distribution of the nanotubes in the dispersion” is understood within the framework of the present invention as meaning that the nanotubes form only a few aggregates, if any, and that, in the case where such aggregates are formed, they are preferably very small (below 1 μm²), and that they are distributed throughout the dispersion.

“Bare” nanotubes are understood within the framework of the present invention as meaning nanotubes which have not undergone any surface modification treatment, be it chemical treatment or complexation.

Thus a first subject of the invention is complexed carbon nanotubes consisting of bare carbon nanotubes having a layer of at least one pigment directly adsorbed on their outer periphery, and at least one polymer having at least one anchoring point on said layer of at least one pigment.

According to the invention the nanotubes can be Single-wall nanotubes (SWNT), double-wall nanotubes (DWNT), multi-wall nanotubes (MWNT), nanotubes grown in the vapor phase (VGCF), nanofibers or a cylindrical carbon structure, and mixtures thereof.

Preferably, the nanotubes are Single-wall nanotubes, double-wall nanotubes, multi-wall nanotubes or mixtures thereof.

Particularly preferably, the nanotubes are Single-wall nanotubes.

As far as the pigment is concerned, this can be an inorganic pigment treated so as to be compatible with a polymer or an organic solvent, or an organic pigment such as azo pigments, yellow and orange monoazo pigments, diazo pigments, naphthol pigments, Naphthol AS pigments (naphthol red), azo pigment lakes, benzimidazolone pigments, diazo condensation pigments, complex metal pigments, isoindolinone and isoindoline pigments, polycyclic pigments, phthalocyanine pigments, a sulfonated copper phthalocyanine containing an average of 0.5 to 3 sulfonic acid groups, a ground chlorinated copper phthalocyanine, an aluminum phthalocyanine, a brominated phthalocyanine, an aluminum hydroxide phthalocyanine, a metal-free phthalocyanine, quinophthalone pigments, indathrone pigments, yellow diacrylide pigments, diazopyrazolone pigments, azo-metal pigments, triarylcarbonium pigments, rhodamine lake pigments, perylene pigments, quinacridone pigments and diketopyrrolopyrrole pigments, and mixtures of two or more of these.

Preferably, the pigment is phthalocyanine.

As far as the polymer is concerned, this is selected from the group comprising polymers of one or more organic acids or organic hydroxy acids and derivatives thereof, organic amine, alcohol or thiol polymers, copolymers or block copolymers of one or more organic acids and one or more organic polyamines, polyalcohols or polythiols, styrene/ethylene copolymers, styrene/propylene co-polymers, styrene/butadiene copolymers, styrene/acrylate copolymers, styrene/ methacrylate copolymers and combinations of two or more of these.

Preferably, said polymer is a hydroxyoctadecanoic acid/aziridine block copolymer.

In one preferred embodiment, the weight ratio nanotubes/pigment/polymer is between 1/1/1 and 1/5/1.

Advantageously, the weight ratio nanotubes/pigment/polymer is 1/2/1.

A second subject of the invention is a stable dispersion of carbon nanotubes comprising the nanotubes according to the first subject of the invention uniformly distributed in an organic solvent in which said at least one polymer is soluble.

The organic solvent is selected from the group comprising the aliphatic hydrocarbons heptane, octane and decane, the aromatic hydrocarbons benzene, toluene, ethylbenzene and xylene, the halogenated aromatic and aliphatic hydro-carbons monochlorobenzene, dichlorobenzene, dichloroethylene, trichloroethylene, perchloroethylene and carbon tetrachloride, the acetates methyl acetate, ethyl acetate, isopropyl acetate and butyl acetate, the ketones diisobutyl ketone, diisopropyl ketone and methyl propyl ketone, and mixtures of one or more of these.

Preferably, the organic solvent is xylene.

In one preferred embodiment of the dispersion of the invention, the percentage by weight of nanotubes is between 0.01 and 5% inclusive, based on the total weight of the dispersion, the percentage by weight of pigment is between 0.01 and 50% inclusive, based on the total weight of the dispersion, and the ratio of the weight of polymer to the total weight of the dispersion is between 0.01 and 5% inclusive.

A third subject of the invention is a device for vaporizing a dispersion of nanotubes according to the invention which consists of a vessel fitted with a vaporizing device and containing the dispersion according to the invention and a propellant.

A fourth subject of the invention is a process for the manufacture of a dispersion of carbon nanotubes, characterized in that it comprises the following steps:

a) addition of bare nanotubes, at least one polymer and at least one pigment to an organic solvent in which the polymer is soluble, and

b) mixing of the composition obtained in step a).

In one preferred embodiment of the process for the manufacture of a dispersion of nanotubes according to the fourth subject of the invention, step a) comprises the following steps:

a₁) mixing of the nanotubes and said at least one pigment,

a₂) addition to the mixture obtained in step a₁) of an organic solvent in which the polymer is soluble, and

a₃) addition of the at least one polymer to the mixture obtained in step a₂).

In this case the mixing of step a₁) is preferably effected by grinding.

In all cases, in the process for the manufacture of a dispersion of carbon nanotubes according to the fourth subject of the invention, the mixing of step b) is preferably effected by horn sonication.

In one variant of the process for the manufacture of a dispersion of carbon nanotubes according to the fourth subject of the invention, a step c) for evaporation of part of the solvent is provided after step b).

In all cases the process for the manufacture of a dispersion of carbon nanotubes according to the invention is applied to Single-wall nanotubes (SWNT), double-wall nanotubes (DWNT), multi-wall nanotubes (MWNT), nanotubes grown in the vapor phase (VGCF), nanofibers or any cylindrical carbon structure, and mixtures thereof.

Preferably, the nanotubes are Single-wall nanotubes, double-wall nanotubes, multi-wall nanotubes or mixtures thereof.

Particularly preferably, the nanotubes are Single-wall nanotubes.

According to a first characteristic of the process for the manufacture of a dispersion of carbon nanotubes according to the invention, said at least one pigment is selected from the group comprising an inorganic pigment treated so as to be compatible with a polymer or an organic solvent, azo pigments, yellow and orange monoazo pigments, diazo pigments, naphthol pigments, Naphthol AS pigments (naphthol red), azo pigment lakes, benzimidazolone pigments, diazo condensation pigments, complex metal pigments, isoindolinone and isoindoline pigments, polycyclic pigments, phthalocyanine pigments, a sulfonated copper phthalocyanine containing an average of 0.5 to 3 sulfonic acid groups, a ground chlorinated copper phthalocyanine, an aluminum phthalocyanine, a brominated phthalocyanine, an aluminum hydroxide phthalocyanine, a metal-free phthalocyanine, quinophthalone pigments, indathrone pigments, yellow diacrylide pigments, diazopyrazolone pigments, azo-metal pigments, triarylcarbonium pigments, rhodamine lake pigments, perylene pigments, quinacridone pigments and diketopyrrolopyrrole pigments, and mixtures of two or more of these.

In this case said at least one pigment is preferably phthalocyanine.

According to another characteristic of the process for the manufacture of a dispersion of carbon nanotubes according to the invention, said polymer is selected from the group comprising polymers of one or more organic acids or organic hydroxy acids and derivatives thereof, organic amine, alcohol or thiol polymers, copolymers or block copolymers of one or more organic acids and one or more organic polyamines, polyalcohols or polythiols, styrene/ethylene copolymers, styrene/propylene copolymers, styrene/butadiene copolymers, styrene/acrylate copolymers, styrene/methacrylate copolymers and combinations of two or more of these.

Preferably, said polymer is a hydroxyoctadecanoic acid/aziridine block copolymer.

In one preferred embodiment of the invention of the process for the manufacture of a dispersion of carbon nanotubes according to the invention, the weight ratio nanotubes/pigment/polymer is between 1/1/1 and 1/5/1.

Particularly preferably, the weight ratio nanotubes/pigment/polymer is 1/2/1.

According to yet another characteristic of the process for the manufacture of a dispersion of carbon nanotubes according to the invention, the organic solvent is selected from the group comprising the aliphatic hydrocarbons heptane, octane and decane, the aromatic hydrocarbons benzene, toluene, ethylbenzene and xylene, the halogenated aromatic and aliphatic hydrocarbons monochlorobenzene, dichlorobenzene, dichloroethylene, trichloroethylene, perchloroethylene and carbon tetrachloride, the acetates methyl acetate, ethyl acetate, isopropyl acetate and butyl acetate, the ketones diisobutyl ketone, diisopropyl ketone and methyl propyl ketone, and mixtures of one or more of these.

Preferably, the organic solvent is xylene.

In general, in the process for the manufacture of a dispersion of carbon nanotubes according to the invention, the percentage by weight of nanotubes is between 0.01 and 5% inclusive, based on the total weight of the dispersion, the percentage by weight of pigment is between 0.01 and 50% inclusive, based on the total weight of the dispersion, and the percentage by weight of polymer is between 0.01 and 5% inclusive, based on the total weight of the dispersion.

A fifth subject of the invention is a process for the manufacture of a dispersion of carbon nanotubes which consist in placing the nanotubes according to the first subject of the invention, in powder form, in an organic solvent in which the polymer, anchored to the layer of pigment coating the outer periphery of the nanotubes, is soluble, and in mixing the solvent and the nanotubes of the invention by agitation.

According to one characteristic of this process for the manufacture of a dispersion of carbon nanotubes, the organic, solvent is selected from the group comprising the aliphatic hydrocarbons heptane, octane and decane, the aromatic hydrocarbons benzene, toluene, ethylbenzene and xylene, the halogenated aromatic and aliphatic hydrocarbons monochlorobenzene, dichlorobenzene, dichloroethylene, trichloroethylene, perchloroethylene and carbon tetrachloride, the acetates methyl acetate, ethyl acetate, isopropyl acetate and butyl acetate, the ketones diisobutyl ketone, diisopropyl ketone and methyl propyl ketone, and mixtures of two or more of these.

Preferably, the organic solvent is xylene.

As a further preference, according to the fifth subject of the invention, the step for mixing of the organic solvent and the nanotubes by agitation is effected by horn sonication.

A sixth subject of the invention is a process for the manufacture of carbon nanotubes according to the first subject of the invention, characterized in that it comprises the steps of the process for the manufacture of a dispersion according to the fourth or fifth subject of the invention, followed by a step d) for total evaporation of the solvent.

A seventh subject of the invention is a composite material of the type comprising a water-insoluble organic matrix and carbon nanotubes, characterized in that the carbon nanotubes are nanotubes according to the invention.

An eighth subject of the invention is the use of the nanotubes according to the first subject of the invention, or obtained by the process according to the sixth subject of the invention, for the manufacture of articles made of a composite material.

A ninth subject of the invention is the use of the dispersion according to the second subject of the invention, or obtained by the process according to the fourth or fifth subject of the invention, for the manufacture of articles made of a composite material.

In these last two subjects, the article is a film or thin layer in particular.

A tenth subject of the invention is the use of the device according to the third subject of the invention for the manufacture of films or thin layers.

An eleventh subject of the invention is a process for the manufacture of an article made of a composite material of the type comprising a polymer matrix that is insoluble in or immiscible with water, and carbon nanotubes, characterized in that it comprises the steps for the manufacture of a dispersion of nanotubes by the process according to the fourth or fifth subject of the invention, followed by a step e) for dissolution of the material constituting the water-insoluble polymer matrix in an organic solvent in which the material constituting the polymer matrix is soluble, a step f) for mixing of the solution obtained in step e) with the dispersion of nanotubes obtained by the process according to the fourth or fifth subject of the invention, and a step g) for shaping of the desired article, and in that the solvent used to manufacture the dispersion of nanotubes and the solvent used to dissolve the material constituting the polymer matrix are mutually soluble or miscible.

Preferably, the two solvents are identical.

In this process the polymer matrix is selected from the group comprising the thermoplastic polymers polystyrene, polymethyl methacrylate, polyvinyl chloride, polyethylene, polyethylene terephthalate, polymethylene oxide, polyacrylonitrile, polyesters, polyurethanes and polyamides, and mixtures and copolymers of two or more of these.

Preferably, the polymer matrix is a polyamide.

The invention will be better understood and other advantages and characteristics thereof will become more clearly apparent from the following explanatory description given with reference to the attached Figures, in which:

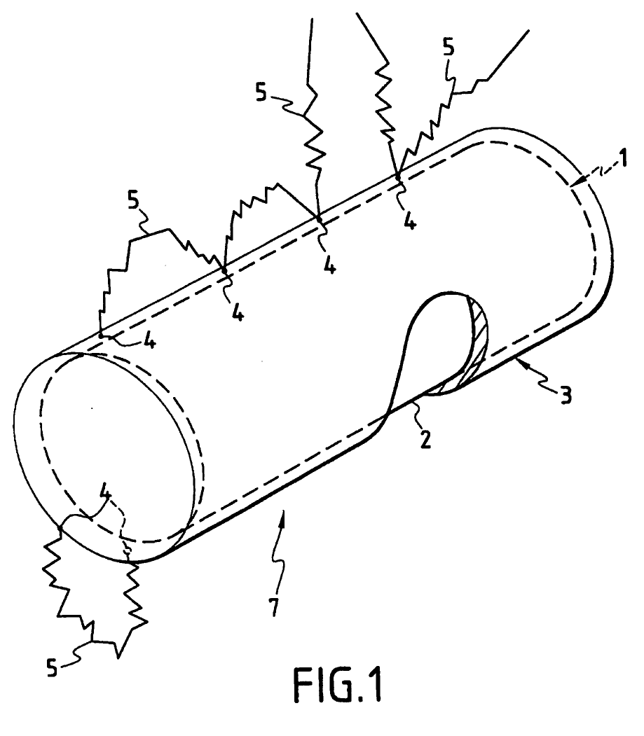

FIG. 1 shows a partially cut-away perspective of a nanotube according to the invention,

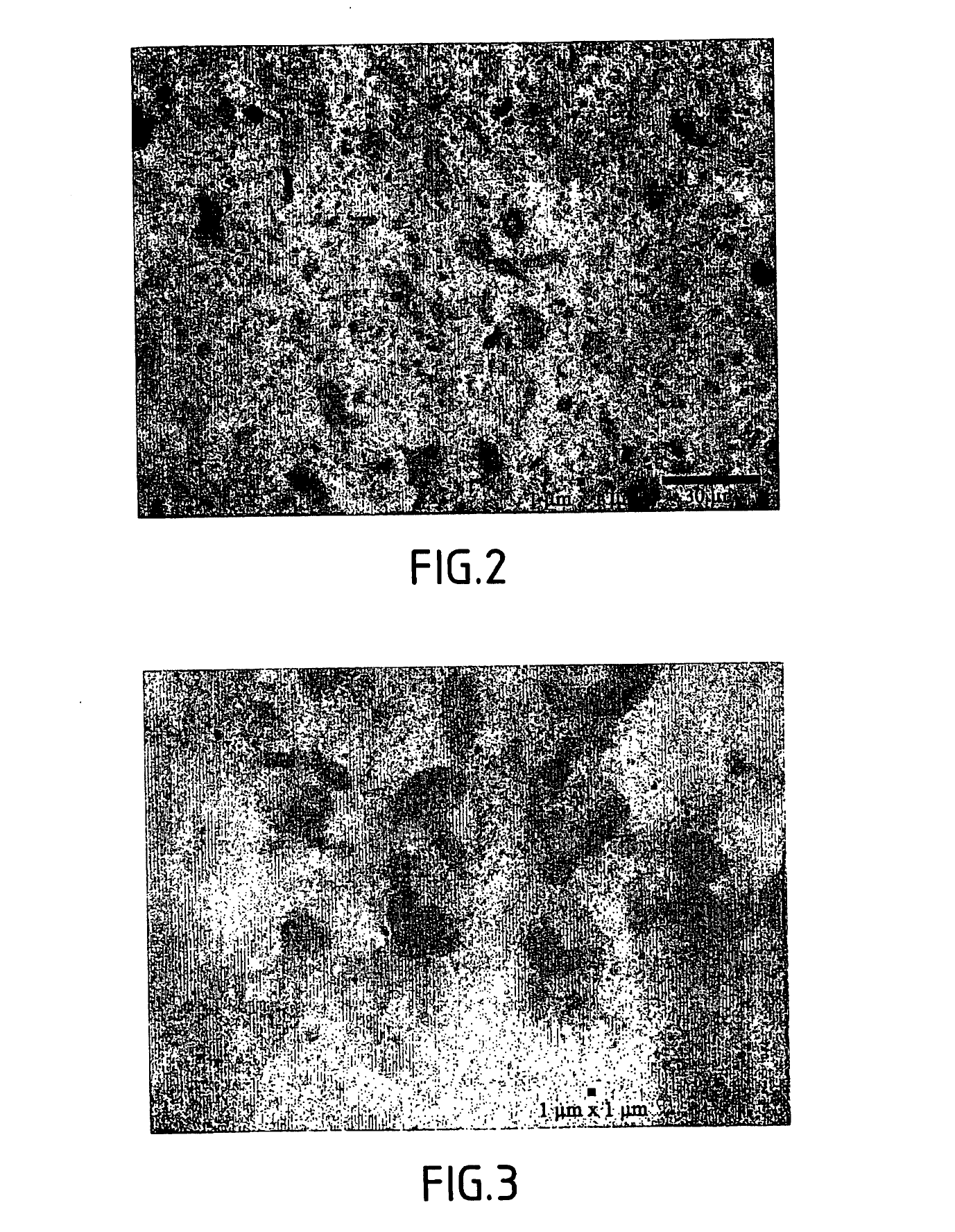

FIG. 2 shows an optical micrograph, at a magnification of 60, of a dispersion according to the invention, denoted by XFF09 in the following description,

FIG. 3 shows an optical micrograph, at a magnification of 60, of another dispersion according to the invention, denoted by XFF05 in the following description, and

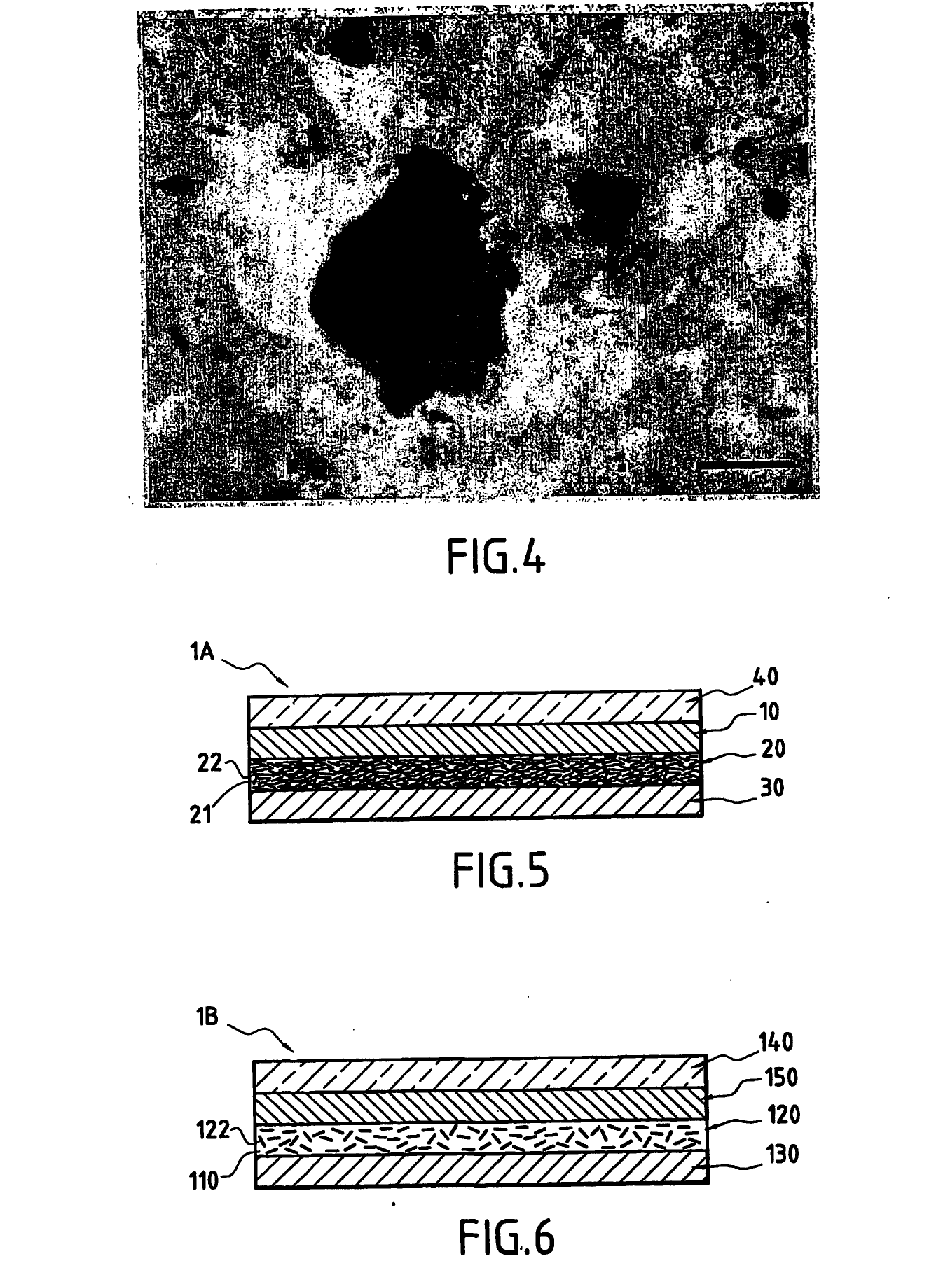

FIG. 4 shows an optical micrograph, . . . a magnification of 60, of a dispersion that does not fall within the framework of the invention, denoted by XFF010 in the following description.

In the description, the claims and the Figures which follow, reference number 1 denotes “bare” carbon nanotubes as defined above, reference number 2 denotes the outer periphery of these nanotubes 1 in contact either with air or with the solvent(s), or the polymer matrix, before their treatment according to the invention, and reference number 7 denotes the “complexed” carbon nanotubes according to the invention.

The “complexed” carbon nanotubes according to the invention will be described first of all with reference to FIG. 1.

As seen in FIG. 1, the “bare” carbon nanotube, as purchasable commercially and not treated according to the invention, is denoted by 1 and the nanotube according to the invention is denoted by 7.

The nanotube 7 therefore consists of the “bare” nanotube 1 which has been coated with a layer of at least one pigment 3. The layer of pigment 3 is adsorbed on the outer peripheral surface, denoted by 2, of the nanotube 1.

The layer of pigment 3 coats only the outer surface of the nanotubes.

In fact, the nanotubes consist of a sheet of graphite rolled onto itself. However, this tube is “plugged” at the ends by two hemispheres, making the inside of the nanotube inaccessible to the pigment(s) and polymer(s). The pigment 3 therefore adsorbs only onto the outer periphery of the nanotubes, since this is the only surface which can be in contact with the pigment 3.

Furthermore, the nanotube 7 according to the invention has at least one polymer 5 bound to the layer of pigment 3 by at least one anchoring point denoted by 4.

As can be seen in FIG. 1, the polymer 5 can have a single anchoring point 4 on the layer of pigment 3 or can have several such points, the rest of the chain of the polymer 5 floating freely and coating and protecting the whole of the nanotube by steric hindrance.

Without wishing to be tied down by theory, it is thought that the pigment 3 is bound to the carbon nanotubes and that the polymer 5 is bound to the layer of pigment 3 by interactions of the van der Waals type.

It is for this reason that “complexation” is understood here as meaning an interaction without chemical bonding.

The polymer 5 can be a linear or branched homopolymer or copolymer, preferably a block copolymer.

Examples are of the polymer 5 of one or more organic acids or organic hydroxy acids and derivatives thereof. In particular, they may be organic amine, alcohol or thiol polymers, copolymers or block copolymers of one or more organic acids with one or more organic polyamines, polyalcohols or polythiols, styrene/ethylene copolymers, styrene/propylene copolymers, styrene/butadiene copolymers, styrene/acrylate copolymers, styrene/methacrylate copolymers and combinations of two or more of these.

Preferably, said polymer is a hydroxyoctadecanoic acid/aziridine block copolymer.

The weight ratio nanotubes 1/pigment 3/polymer 5 may vary according to the specific surface area of the “bare” carbon nanotubes. It is preferably between 1/1/1 and 1/5/1 and particularly preferably 1/2/1.

The nanotubes of the invention as described above are in powder form and can therefore easily be stored, transported and handled.

However, as seen above, if they are to be used as a filler in a polymer matrix, it is necessary to prepare a stable dispersion having a uniform distribution of carbon nanotubes.

It will be recalled here that a dispersion is considered to be stable when there is no deposit at the bottom of the vessel after 4 days or even several months.

In the case of an unstable dispersion, this deposit is due to aggregation of the suspended particles during the different treatments they have undergone in the manufacture of the dispersion, particularly during the ultrasound treatment.

“Uniform distribution of the carbon nanotubes” is understood as meaning that the distribution of the carbon nanotubes is homogeneous throughout the dispersion, i.e. that the carbon nanotubes are homogeneously distributed at every point of the dispersion.

Thus one criterion which makes it possible to refine the notion of “uniform distribution” of the carbon nanotubes in the dispersion is the size of the aggregates: the smaller these aggregates, the more uniform is the dispersion because there is less agglomeration of nanotubes.

However, a dispersion can be stable and have a uniform distribution of carbon nanotubes, but with a uniformity of large aggregates. This is not the preferred case, albeit accepted within the framework of the invention.

The perfect case is a stable uniform dispersion having a homogeneous distribution in the dispersion of very small aggregates or no aggregates at all, in which case the nanotubes are perfectly individualized.

Thus “uniform distribution” is understood as meaning a homogeneous distribution of aggregates of nanotubes in the dispersion, these aggregates not exceeding a limiting size corresponding to a distribution that is certainly uniform, but not homogeneous.

Thus the size of the aggregates is one criterion, but this criterion has to be modified according to the concentration of nanotubes in the dispersion.

Thus, by comparing FIGS. 2, 3 and 4, it is seen that FIG. 2 shows a dispersion having a uniform distribution of very small aggregates of carbon nanotubes, FIG. 3 shows another dispersion having a uniform distribution of larger aggregates of nanotubes, and FIG. 4 shows a dispersion which does not have a uniform distribution of nanotubes, these nanotubes being grouped into large aggregates, whereby they are not distributed homogeneously throughout the dispersion.

The nanotubes 7 of the invention can be redispersed in organic solvent 6 in which the polymer 5 is soluble, this taking place in a stable manner with a uniform distribution. In these dispersions the concentration by weight of nanotubes 7 can vary between 0.01% and 5% inclusive, typically from 0.2% to 5% by weight, the remainder being the organic solvent.

The organic solvent 6 is an organic liquid medium. It can be a polar organic solvent or, more preferably, an apolar organic solvent. The term “apolar” denotes an organic liquid or a resin whose dielectric constant ε is typically below 9.5.

Examples of the organic solvent 6 are the aliphatic hydrocarbons heptane, octane and decane, the aromatic hydrocarbons benzene, toluene, ethylbenzene and xylene, the halogenated aromatic and aliphatic hydrocarbons monochlorobenzene, dichlorobenzene, dichloroethylene, trichloroethylene, perchloroethylene and carbon tetrachloride, the acetates methyl acetate, ethyl acetate, isopropyl acetate and butyl acetate, the ketones diisobutyl ketone, diisopropyl ketone and methyl propyl ketone, and mixtures of two or more of these.

This redispersion of the nanotubes is effected simply by mixing the nanotubes in the chosen solvent 6 in which the polymer 5 is soluble, at ambient temperature.

The dispersion obtained is stable for several months and the complexed nanotubes 7 are uniformly distributed in this dispersion, as can be seen in FIG. 2.

However, such a dispersion of nanotubes in the organic solvent 6 defined above can also be obtained directly.

Thus a process according to the invention for obtaining a stable dispersion of carbon nanotubes in the organic solvent 6 comprises the following steps:

a) addition of nanotubes 1, at least one polymer 5 and at least one pigment 3 to an organic solvent 6 in which the polymer 5 is soluble, and

b) mixing of the composition obtained in step a).

In one preferred embodiment, step a) comprises the following steps:

a₁) mixing of the nanotubes and said at least one pigment 3,

a₂) addition to the mixture obtained in step a₁) of an organic solvent 6 in which the polymer 5 is soluble, and

a₃) addition to the mixture obtained in step a₂) of the at least one polymer 5.

Preferably, the mixing of step b) is effected by horn sonication.

To increase the concentration of nanotubes in this dispersion, this process also comprises, after step b), a step c) for evaporation of part of the solvent 6.

In this process the nanotubes 1, 7, the organic solvent 6, the polymer 5 and the pigment 3 forming part of the composition of these dispersions are the same as those described above.

Likewise, the proportions and concentrations by weight of carbon nanotubes 1, 7, pigment 3, polymer 5 and organic solvent 6 are identical to those described above.

The nanotubes of the invention can be obtained in powder form from this dispersion by carrying out a total evaporation of the solvent after step b).

The dispersions of the invention may be used as such for the manufacture of a composite material or an article made of a composite material.

In one particularly advantageous embodiment of the invention, the dispersions will be placed in a vessel comprising a vaporizing device and a propellant such as a gas, optionally a liquefied gas. Such a device will be particularly advantageous for producing films or thin layers of carbon nanotubes.

In this case a film-forming agent or a binder, such as a resin or a surfactant, may be added to the dispersion of carbon nanotubes according to the invention.

The size of the aggregates of carbon nanotubes is also observed after four days and after several months.

The nanotubes according to the invention and the dispersions according to the invention may be used in a very simple manner for the manufacture of composite materials or articles made of a composite material.

“Article made of a composite material” is understood to include films and thin layers which may also be manufactured even without using the vaporizing device of the invention.

A typical process for the manufacture of a composite material or an article made of a composite material of the type comprising a water-insoluble polymer matrix and carbon nanotubes comprises the steps of the processes for the manufacture of a dispersion of nanotubes according to the invention, followed by

a step e) for dissolution of the material constituting the water-insoluble polymer matrix in an organic solvent 7 in which the material constituting the polymer matrix is soluble,

a step f) for mixing of the solution obtained in step e) with the dispersion of nanotubes obtained by the process according to the invention, and

a step g) for shaping of the desired article,

the solvent 6 used to manufacture the dispersion of nanotubes and the solvent 7 used to dissolve the material constituting the polymer matrix being mutually soluble.

Preferably, the solvent 6 and the solvent 7 are identical.

The polymer matrix to which the nanotubes 7 are added can be made of any water-insoluble polymer material such as the thermoplastic polymers polystyrene, polymethyl methacrylate, polyvinyl chloride, polyethylene, polyethylene terephthalate, polymethylene oxide, polyacrylonitrile, polyesters, polyurethanes and polyamides, and mixtures and copolymers of two or more of these.

To provide a better understanding of the invention, several embodiments thereof, which are given purely by way of illustration and without implying a limitation, will now be described.

Firstly, 17 dispersions of carbon nanotubes having different concentrations by weight of nanotubes 1, pigment 3 and polymer 5 were prepared. The amount of solvent was kept constant, except for the sample XF002.

The 17 dispersions obtained were then tested for stability and for uniform distribution of the carbon nanotubes, as described above.

The carbon nanotubes used were “bare” carbon nanotubes manufactured and marketed by NANOLEDGE S.A., Montpellier, France.

The pigment used was a mixture of phthalocyanine-based pigments marketed by AVECIA S.A./N.V., Brussels, Belgium, under the registered trade mark Solsperse RTM 5000®.

The polymer was a hydroxyoctadecanoic acid/aziridine block copolymer marketed by AVECIA S.A./N.V., Brussels, Belgium, under the registered trade mark Solsperse RTM 24000SC®. The solvent was xylene (mixture of isomers, puriss. p.a.) marketed by SIGMA-ALDRICH CHIMIE S.A.R.L., 38299 Saint Quentin Fallavier Cedex.

Each of these 17 dispersions was then observed under an optical microscope at a magnification of 60 in order to evaluate the possible presence of aggregates of nanotubes and, if aggregates of nanotubes were present, to evaluate the size of these aggregates. This measurement is representative of the uniform or non-uniform distribution of the carbon nanotubes in the dispersion.

The Tables show the size of the aggregates on a scale of 1 to 5:

the notation 5 corresponds to an aggregate size above 100,000 nm,

the aggregate size notation 4 denotes aggregates with a size below 100,000 nm but above 10,000 nm,

the notation 3 denotes aggregates with a size below 10,000 nm but above 1000 nm,

the notation 2 denotes aggregates with a size below or equal to 1000 nm, and

the notation 1 denotes aggregates with a size below 1000 nm or, more preferably, equal to 250 nm.

It was seen that the smaller the aggregate size, the more uniform is the distribution of the carbon nanotubes in the dispersion.

Each of these dispersions was then stored at ambient temperature for four days and four months and they were re-examined after each of these periods to determine whether there was a precipitation and/or reagglomeration of the carbon nanotubes.

### COMPARATIVE EXAMPLE 1

### Denoted by XF001 in Table 1

In this case, and by way of comparison, a dispersion of carbon nanotubes was prepared without using polymer.

10.0 mg of “bare” nanotubes (1) were mixed with 20.0 mg of pigment by dry grinding in a ball mill.

The weight ratio nanotubes 1/pigment 3/polymer 5 is thus 1/2/0 in this Example.

5000.3 mg of xylene were then added to this mixture and the whole was mixed by bath sonication for 2×15 minutes.

### COMPARATIVE EXAMPLE 2

### Denoted by XF002 in Table 1

This dispersion was also prepared by way of comparison.

In this Example the dispersion of carbon nanotubes was prepared without using pigment. Thus 6.8 mg of bare carbon nanotubes were mixed with 3.7 mg of polymer by dry grinding in a ball mill. The weight ratio nanotubes/pigment/polymer is 1/0/0.54.

2503.0 mg of solvent are added to this mixture and the whole is mixed by bath sonication for 2×15 minutes.

The results of the aggregate size and stability measurements are shown in Table 1.

### COMPARATIVE EXAMPLE 3

### Denoted by XF010 in Table 1

10.1 mg of bare nanotubes and 8.4 mg of polymer are mixed by dry grinding in a ball mill. There was no pigment in this case.

The weight ratio nanotubes/pigment/polymer is 1/0/0.83 in this Example.

4951.0 mg of xylene are added to the ground mixture obtained and the whole is mixed by bath sonication for 2×15 minutes.

The results of evaluation of the stability and uniform distribution of the nanotubes in this dispersion are shown in Table 1.

### EXAMPLE 1

### denoted by XF003 in Table 1

9.5 mg of bare carbon nanotubes, 12.3 mg of pigment and 4.0 mg of polymer, i.e. a weight ratio nanotubes/pigment/polymer of 1/0.3/0.42, were mixed by dry grinding in a ball mill.

5000.13 mg of xylene are added to this mixture and the whole is mixed by bath sonication for 2×15 minutes.

The results of evaluation of the stability and uniform distribution of the dispersion obtained are shown in Table 1.

### EXAMPLE 2

### Denoted by XF004 in Table 1

9.8 mg of bare carbon nanotubes were mixed with 20.3 mg of pigment and 6.1 mg of polymer by dry grinding in a ball mill.

The weight ratio nanotubes/pigment/polymer is 1/2.07/0.62.

5000.0 mg of xylene are added to this mixture and the whole is mixed by bath sonication for 2×15 minutes.

The results of evaluation of the stability and uniform distribution of the dispersion obtained are shown in Table 1.

### EXAMPLE 3

### Denoted by XF005 in Table 1

9.9 mg of bare carbon nanotubes were mixed with 1.0 mg of pigment and 6.8 mg of polymer by dry grinding in a ball mill.

The weight ratio nanotubes/pigment/polymer is 1/0.1/0.69.

5035.0 mg of xylene are added to this mixture and the whole is mixed by bath sonication for 2×15 minutes.

The results of evaluation of the stability and uniform distribution of the dispersion obtained are shown in Table 1.

### EXAMPLE 4

### Denoted by XF006

10.4 mg of bare carbon nanotubes, 32.6 mg of pigment and 8.3 mg of polymer are mixed by dry grinding in a ball mill.

The weight ratio nanotubes/pigment/polymer is 1/3.1/0.80 in this Example. 5008.0 mg of xylene are added to the ground mixture obtained, with bath sonication for 2×15 minutes.

The results of evaluation of the stability and uniform distribution of the nanotubes in this dispersion are shown in Table 1.

### EXAMPLE 5

### Denoted by XF007 in Table 1

10.3 mg of bare nanotubes, 2.7 mg of pigment and 8.0 mg of polymer are mixed by dry grinding in a ball mill.

The weight ratio nanotubes/pigment/polymer is 1/0.26/0.78 in this Example.

5008.0 mg of xylene are added to the ground mixture obtained and the whole is mixed by bath sonication for 2×15 minutes.

The results of evaluation of the stability and uniform distribution of the nanotubes in this dispersion are shown in Table 1.

### EXAMPLE 6

### Denoted by XF008 in Table 1

10.2 mg of bare nanotubes, 3.9 mg of pigment and 8.2 mg of polymer are mixed by dry grinding in a ball mill.

The weight ratio nanotubes/pigment/polymer is 1/0.38/0.80 in this Example.

5000.2 mg of xylene are added to the ground mixture obtained and the whole is mixed by bath sonication for 2×15 minutes.

The results of evaluation of the stability and uniform distribution of the nanotubes in this dispersion are shown in Table 1.

### EXAMPLE 7

### Denoted by XF009 in Table 1

10.1 mg of bare nanotubes, 10.0 mg of pigment and 8.4 mg of polymer are mixed by dry grinding in a ball mill.

The weight ratio nanotubes/pigment/polymer is 1/1/0.83 in this Example.

5010.0 mg of xylene are added to the ground mixture obtained and the whole is mixed by bath sonication for 2×15 minutes.

The results of evaluation of the stability and uniform distribution of the nanotubes in this dispersion are shown in Table 1.

### EXAMPLE 8

### Denoted by XF011 in Table 1

10.3 mg of bare nanotubes, 1.6 mg of pigment and 8.5 mg of polymer are mixed by dry grinding in a ball mill.

The weight ratio nanotubes/pigment/polymer is 1/0.15/0.82 in this Example.

4991.0 mg of xylene are added to the ground mixture obtained and the whole is mixed by bath sonication for 2×15 minutes.

The results of evaluation of the stability and uniform distribution of the nanotubes in this dispersion are shown in Table 1.

### EXAMPLE 9

### Denoted by XF012 in Table 1

9.8 mg of bare nanotubes, 30.5 mg of pigment and 10.2 mg of polymer are mixed by dry grinding in a ball mill.

The weight ratio nanotubes/pigment/polymer is 1/3.1/1.04 in this Example.

5006.0 mg of xylene are added to the ground mixture obtained and the whole is mixed by bath sonication for 2×15 minutes.

The results of evaluation of the stability and uniform distribution of the nanotubes in this dispersion are shown in Table 1.

### EXAMPLE 10

### Denoted by XF013 in Table 1

10.3 mg of bare nanotubes, 11.2 mg of pigment and 10.3 mg of polymer are mixed by dry grinding in a ball mill.

The weight ratio nanotubes/pigment/polymer is 1/0.1/1 in this Example.

5004.0 mg of xylene are added to the ground mixture obtained and the whole is mixed by bath sonication for 2×15 minutes.

The results of evaluation of the stability and uniform distribution of the nanotubes in this dispersion are shown in Table 1.

### EXAMPLE 11

### Denoted by XF014 in Table 1

9.7 mg of bare nanotubes, 22.7 mg of pigment and 10.5 mg of polymer are mixed by dry grinding in a ball mill.

The weight ratio nanotubes/pigment/polymer is 1/2.34/1.08 in this Example.

4994.0 mg of xylene are added to the ground mixture obtained and the whole is mixed by bath sonication for 2×15 minutes.

The results of evaluation of the stability and uniform distribution of the nanotubes in this dispersion are shown in Table 1.

Example 12: denoted by XF015 in Table 1

10.3 mg of bare nanotubes, 20.2 mg of pigment and 15.3 mg of polymer are mixed by dry grinding in a ball mill.

The weight ratio nanotubes/pigment/polymer is 1/1.96/1.48 in this Example.

4994.0 mg of xylene are added to the ground mixture obtained and the whole is mixed by bath sonication for 2×15 minutes.

The results of evaluation of the stability and uniform distribution of the nanotubes in this dispersion are shown in Table 1.

Example 13: denoted by XF016 in Table 1

10.3 mg of bare nanotubes, 47.5 mg of pigment and 16.4 mg of polymer are mixed by dry grinding in a ball mill.

The weight ratio nanotubes/pigment/polymer is 1/4.61/1.59 in this Example.

4995.0 mg of xylene are added to the ground mixture obtained and the whole is mixed by bath sonication for 2×15 minutes.

The results of evaluation of the stability and uniform distribution of the nanotubes in this dispersion are shown in Table 1.

Example 14: denoted by XF017 in Table 1

10.1 mg of bare nanotubes, 20.6 mg of pigment and 33.2 mg of polymer are mixed by dry grinding in a ball mill.

The weight ratio nanotubes/pigment/polymer is 1/2/3.3 in this Example.

5003.0 mg of xylene are added to the ground mixture obtained and the whole is mixed by bath sonication for 2×15 minutes.

The results of evaluation of the stability and uniform distribution of the nanotubes in this dispersion are shown in Table 1.

TABLE 1

| | Weight of | Weight of | Weight of | Weight ratio | Weight of | |
|---|---|---|---|---|---|---|
| Dispersion | nanotubes in mg | pigment in mg | polymer in mg | nanofibers/pigment/polymer | xylene in mg | Aggregates |
| XF001 | 10.0 | 20.0 | 0 | 1/2/0 | 5000.3 | 5 |
| XF002 | 6.8 | 0.0 | 3.7 | 1/0/0.5 | 2503.0 | 5 |
| XF010 | 10.1 | 0.0 | 8.4 | 1/0/0.8 | 4951.0 | 5 |
| XF003 | 9.5 | 12.3 | 4.0 | 1/1.3/0.4 | 5013.0 | 3 |
| XF004 | 9.8 | 20.3 | 6.1 | 1/2.1/0.6 | 5000.0 | 3 |
| XF005 | 9.9 | 1.0 | 6.8 | 1/0.1/0.7 | 5035.0 | 3 |
| XF006 | 10.4 | 32.6 | 8.3 | 1/3.1/0.8 | 5000.0 | 4 |
| XF007 | 10.3 | 2.7 | 8.0 | 1/0.26/0.8 | 5008.0 | 3 |
| XF008 | 10.2 | 3.9 | 8.2 | 1/0.38/0.8 | 5002.0 | 3 |
| XF009 | 10.1 | 10.0 | 8.4 | 1/1/0.8 | 5010.0 | 3 |
| XF011 | 10.3 | 1.6 | 8.5 | 1/0.15/0.8 | 4991.0 | 3 |
| XF012 | 9.8 | 30.5 | 10.2 | 1/3.1/1 | 5006.0 | 2 |
| XF013 | 10.1 | 11.2 | 10.3 | 1/0.1/1 | 5004.0 | 3 |
| XF014 | 9.7 | 22.7 | 10.5 | 1/2.34/1.1 | 4994.0 | 1 |
| XF015 | 10.3 | 20.2 | 15.3 | 1/1.96/1.5 | 4994.0 | 3 |
| XF016 | 10.3 | 47.5 | 16.4 | 1/4.61/1.6 | 4995.0 | 2 |
| XF017 | 10.1 | 20.6 | 33.2 | 1/2/2.3 | 5003.0 | 3 |

All the dispersions obtained using both pigment and polymer were stable, i.e. they exhibited neither precipitation nor reagglomeration of the nanotubes after 4 days of storage at ambient temperature, whereas the dispersions obtained using either polymer or pigment on its own were only stable for a few minutes.

All the dispersions stable after 4 days of storage at ambient temperature were also stable after 4 months. They even showed an improvement, since it was noted in this case that the size of the aggregates of carbon nanotubes decreased, the uniform and homogeneous dispersion being preserved and there being no deposit at the bottom of the storage vessel.

It is seen from Table 1 that the dispersions obtained with neither pigment nor polymer all exhibit an aggregate size of 5, showing that they did not have a uniform distribution.

Thus the dispersion will be considered to have a uniform distribution when the notation assigned to the aggregate size is 2 or 1.

It is seen from Table 1 that the dispersions obtained in Example 10 (denoted by XF012 in Table 1), Example 12 (denoted by XF014 in Table 1) and Example 14 (denoted by XF016 in Table 1) afford a stable dispersion having a uniform distribution of the carbon nanotubes.

Thus, although this ratio can vary according to the specific surface area of the bare carbon nanotubes used to manufacture the carbon nanotubes of the invention, and the dispersions of bare carbon nanotubes used to manufacture the carbon nanotubes of the invention and the dispersions of carbon nanotubes of the invention, the preferred weight ratios nanotubes/pigment/polymer are between 1/5/1 and 1/2/1, the best results being obtained with a weight ratio nanotubes/pigment/ polymer of 1/2/1.

The aim of the following experiments was to find the best method of manufacturing the dispersions and nanotubes according to the invention.

The weight ratio nanotubes/pigment/polymer was kept constant at 1/2/1 for these experiments.

The amounts of solvent and pigment were varied, as was the method of mixing the pigment with the carbon nanotubes and the polymer in the solvent.

Fourteen novel dispersions, all having a weight ratio nanotubes/pigment/polymer of 1/2/1, were prepared.

The bare nanotubes, the pigment, the polymer and the solvent used to prepare these dispersions are the same as those used to prepare the dispersions XF001 to XF017 described above.

The different weights of nanotubes, pigment, polymer and solvent, in mg, are shown in Table 2 below.

The final concentration by weight of nanotubes in the dispersion obtained is also shown in Table 2, together with the results of evaluation of the stability and uniform distribution of the nanotubes in the dispersion.

The operating conditions for the preparation of these dispersions are indicated in Table 3.

In Table 3:

BM indicates that the nanotube/pigment/polymer mixture, whether prepared in a single step a) or in three steps denoted by a₁), a2) and a₃) in the foregoing description, was prepared by hand grinding in a porcelain mortar, and that a few drops of solvent were added when these powders were ground.

BBS indicates that the nanotube/pigment/polymer or nanotube/pigment mixture was prepared by dry grinding, without a solvent, in a Retsch MM 2000 automatic vibratory mill from Bioblock Scientific, Illkirch, France, power 600 watt, frequency 20 kHz, with a single steel ball placed inside, an amplitude setting of 70 being re-used for the time specified in Table 3.

BBH indicates that the nanotube/pigment/polymer or nanotube/pigment mixture was prepared in the same mill as above, under the same conditions, except that the initial powders are wetted with a few drops of solvent.

All the solvent is then added to the nanotube/pigment or nanotube/pigment/ polymer mixture and the whole is mixed for the time indicated in Table 3. This mixing is effected either by bath sonication, denoted by SB, or by horn sonication, denoted by SC in Table 3.

Bath sonication corresponds to ultrasound treatment of the dispersion, the ultrasound being generated in a DELTASONIC P500 S/R bath. The dispersion is contained in a vessel and immersed in a bath of distilled water, the ultrasound being transmitted to the sample through the bath. The treatment time is specified in Table 3.

Horn sonication treatment corresponds to treatment of the dispersion with ultrasound generated by a horn. The equipment used is a BIOBLOCK SCIENTIFIC VIBRACELL 75455 apparatus with a pulse setting of 4 and an amplitude setting of 60. The dispersion is contained in a glass vessel, which is immersed in a bath of distilled water. The purpose of the bath is exclusively to cool the sample during application of the ultrasound, and not to transmit the energy. In fact, the ultrasound-generating horn is immersed directly in the dispersion and the ultrasound is applied directly.

In certain cases a step for partial evaporation of the solvent was performed in order to concentrate the dispersion. This is done by placing the dispersion in a heat-resistant glass vessel, which is heated by means of a hotplate equipped with a magnetic mixer. Heating is maintained for the time specified in Table 3, the sample being agitated at the same time. The agitation time, denoted by A, is indicated in Table 3.

The following experiment was also carried out in order to optimize these conditions:

### EXAMPLE 15

### Sample XFF013

25.2 mg of bare nanotubes, 50.8 mg of pigment and 524.3 mg of xylene are mixed by wet grinding in a ball mill.

4483.1 mg of xylene are added to the ground mixture obtained and a horn sonication treatment is applied to the resulting mixture for 30 minutes.

25.8 mg of polymer are then added.

The weight ratio nanotubes/pigment/polymer is 1/2/1.

4605.2 mg of xylene are then evaporated off. The resulting dispersion has a nanotube concentration of 5% by weight, based on the total weight of the dispersion, and remains stable for several months.

TABLE 2

| | Weight of | Weight of | Weight of | Weight of | Final concentration of | |
|---|---|---|---|---|---|---|
| Sample | nanotubes in mg | pigment in mg | polymer in mg | xylene in mg | nanotubes in % by weight | Aggregates |
| XFF001 | 10.01 | 23.00 | 10.90 | 5000 | 0.2 | 4 |
| XFF002 | 100.00 | 230.00 | 100.00 | 5000 | 1.9 | 4 |
| XFF003 | 50.70 | 104.00 | 59.00 | 5000 | 1.0 | 4 |
| XFF004 | 100.70 | 202.00 | 100.00 | 5000 | 1.9 | 4 |
| XFF005 | 50.10 | 115.00 | 55.00 | 5000 | 1.0 | 3 |
| XFF006 | 52.00 | 102.00 | 50.00 | 5000 | 1.0 | 3 |
| XFF007 | 25.00 | 54.00 | 25.00 | 5000 | 0.5 | 2 |
| XFF008 | 300.00 | 600.00 | 300.00 | 15,000 | 1.9 | 3 |
| XFF009 | 66.00 | 136.00 | 69.00 | 3300 | 1.8 | 2 |
| XFF010 | 200.00 | 400.00 | 202.00 | 10,000 | 1.9 | 5 |
| XFF011 | 150.00 | 300.00 | 165.00 | 7500 | 1.9 | 3 |
| XFF012 a | 200.85 | 403.04 | 198.36 | 38,970 | 0.5 | 2 |
| XFF012 b | 401.71 | 806.09 | 396.71 | 38,970 | 1.0 | 3 |
| XFF012 c | 803.43 | 612.17 | 793.43 | 38,970 | 2.0 | 3 |
| XFF013 | 25.2 | 50.5 | 25.8 | 402 | 5.0 | 3 |

TABLE 3

| | BM | BBS | BBH | SB | SC | E | A |
|---|---|---|---|---|---|---|---|
| XFF001 | 2 min | | | 30 min | | | |
| XFF002 | 2 min | | | 30 min | | | |
| XFF003 | 2 min | | | | | | 750 min |
| XFF004 | 2 min | | | | | | 750 min |
| XFF005 | 2 min | | | | 30 min | X | |
| XFF006 | 2 min | | | | | X | |
| XFF007 | | | | | 60 min | X | |
| XFF008 | 2 min | | | | 60 min | | |
| XFF009 | | 3 min | | | 30 min | X | 840 min |
| XFF010 | | | 3 min | | 30 min | X | |
| XFF011 | | | 5 min | | 60 min | X | |
| XFF012 a | | | 3 min | | 75 min | | |
| XFF012 b | | | 3 min | | 75 min | X | |
| XFF012 c | | | 3 min | | 75 min | x | |
| XFF013 | | | 3 min | | 30 min | X | |

The results of evaluation of the stability and uniform distribution of the nanotubes in the dispersions obtained show that only the dispersions XFF009, XFF007 and XFF005 are dispersions that are not only stable but also have a uniform distribution of carbon nanotubes, as can be seen by comparing FIGS. 2, 3 and 1, which show photographs of the dispersion XFF005 (FIG. 2), the dispersion XFF009 (FIG. 3) and the dispersion XFF010 (FIG. 4), taken under an optical microscope at a magnification of 60.

It is seen that the size of the aggregates in the dispersion XFF005 and XFF009 are distinctly smaller than the size of the aggregates in the dispersion XFFO010, indicating a uniform distribution of the carbon nanotubes in the dispersions XFF005 and XFF009, but not in the dispersion XFF010. This is the reason why it is considered that a horn ultrasound treatment combined with grinding in a ball mill, preferably wet grinding, followed by a partial evaporation of the solvent is the best method of obtaining concentrated stable dispersions having a uniform distribution of nanotubes.

It will also be noted that the lower the concentration of carbon nanotubes, the smaller are the aggregates. However, it is seen from Example 15 that the concentration of “bare” nanotubes can be increased to at least 5% by weight, based on the total weight of the dispersion, to give a satisfactory dispersion in an organic solvent.

A complete evaporation of the solvent was then carried out on the dispersion XFF013.

This gives a powder consisting of separate nanotubes. The mixture can be redispersed by adding e.g. 5 ml of xylene, with vigorous agitation. The resulting dispersion is stable and has a uniform distribution.

The resulting dispersion was used to produce polyamide fibers filled with carbon nanotubes. To do this, the polyamide was dissolved in xylene, the previously obtained dispersion of nanotubes was mixed with the polyamide dissolved in xylene, and the mixture obtained was extruded.

Of course, the invention is in no way limited to the embodiments described and illustrated.

Thus, although the carbon nanotubes have been described as sheets of graphite rolled onto themselves, those skilled in the art will understand that carbon nanofibers and carbon particles may be treated in the same way to give stable dispersions having a uniform distribution in an organic solvent and in a solid polymer matrix.

Also, although the polymer described was a block copolymer, any other polymer may be used, particularly branched polymers.

In other words, the invention includes all the technical equivalents of the means described, as well as their combinations if these are effected according to the spirit of the invention.

In a Second Part:

The invention makes it possible to solve various problems concerning photovoltaic conversion.

The invention makes it possible to solve the various stated technical problems by providing for the first time a device such as described below. This device is used mainly for the manufacture of photovoltaic cells.

The invention solves the stated technical problems in that the nanostructures described are capable of effectively inducing photovoltaic conversion, this previous characteristic being due in part to the complexation of a pigment on the nanostructure, but also to the possibility of rapidly dissipating heat as well as charges.

Thus, according to a first feature, the invention relates to a device comprising an electron donor structure containing at least one type of conjugated polymer, and an electron acceptor structure containing at least one type of tubular nanostructure having at least one complexed (i.e. adsorbed) pigment on its surface.

Advantageously, the tubular nanostructures are selected from straight and/or bent Single-wall, double-wall and multi-wall carbon nanotubes (SWNT, DWNT and MWNT) and any mixture of these.

Only in this second part, carbon nanotubes (SWNT, DWNT, MWNT) are understood by the inventors as meaning structures made up essentially of carbon atoms bonded to one another to form a substantially cylindrical molecule generally terminated at the ends by a hemispherical shape, the latter also being made up mainly of carbon atoms bonded to one another. These carbon nanotubes do not necessarily form a perfect structure. Within this framework it is possible e.g. to consider that the multi-wall carbon nanotubes (MWNT) form a kind of nanofiber or nanofibril when these multi-wall carbon nanotubes have a relatively large diameter.

The nanostructures possess an electronegative character, but the subsequent treatments making it possible to render them even more electronegative are very valuable for obtaining the desired properties.

The tubular nanostructures can be halogenated or oxidized (thermally or chemically).

They can also contain more complex groups grafted to the outer surface of the nanostructures. These groups can be linear or branched. They generally comprise carbon atoms, but also heteroatoms such as nitrogen, sulfur, oxygen and phosphorus, as well as any of the functional groups well known to those skilled in the art, such as, in particular, ether, ester, carboxylic acid, amide, amine, carbamate, hydroxyl, isocyanate and halogen groups.

Advantageously, to increase the electrical conductivity of the tubular nanostructure, it can be subjected to a treatment selected from the group comprising doping of the carbon nanotubes with boron, it being possible for multi-wall nanotubes to be doped during synthesis by means of electrical discharge, for example between BN and graphite electrodes, or for Single-wall nanotubes to be doped by partial substitution of the carbon atoms by boron atoms, for example with B₂O₃ (gas) under a nitrogen atmosphere at 1500-1700 K.

Advantageously, the tubular nanostructure can undergo a treatment to improve its processability, such as chemical or thermal oxidation of the carbon nanostructures.

These tubular nanostructures possess a carbon structure, as described above, on which a pigment is complexed (adsorbed). This complexation is preferably effected in a similar manner to that described above in the first part of the invention.

The pigments are preferably selected from inorganic pigments treated so as to be compatible with a polymer or an organic solvent, azo pigments, yellow and orange monoazo pigments, diazo pigments, naphthol pigments, Naphthol® AS pigments (naphthol red), azo pigment lakes, benzimidazolone pigments, diazo condensation pigments, complex metal pigments, isoindolinone and isoindoline pigments, polycyclic pigments, phthalocyanine pigments, a sulfonated copper phthalocyanine containing an average of 0.5 to 3 sulfonic acid groups, a chlorinated copper phthalocyanine, an aluminum phthalocyanine, a brominated phthalocyanine, an aluminum phthalocyanine, a metal-free phthalocyanine, quinophthalone pigments, indathrone pigments, yellow diacrylide pigments, diazopyrazolone pigments, azo-metal pigments, triarylcarbonium pigments, rhodamine lake pigments, perylene pigments, quinacridone pigments and diketopyrrolopyrrole pigments, molecules of porphyrin or derivatives thereof, and mixtures of two or more of all the pigments mentioned above.

The invention further relates to any mixture of nanotubes complexed by pigments.

The adsorption of pigments onto the nanotubes makes it possible to improve the absorption of certain wavelengths of incident light. It is thus possible to broaden the absorption spectrum that induces excited states, and thereby to maximize the conversion of light energy to electrical energy within the cell.

Advantageously, the complexation of pigments on the surface of the nanostructures additionally contributes to homogeneous dispersion of the tubular nanostructures in the conjugated polymer matrix.

Advantageously, the tubular nanostructures serve as dissociation centers for the excited states (electron trap) of the excited pigment molecules.

Advantageously, the tubular nanostructures provide a conduction network for the electrons supplied by the excited pigment molecules.

Advantageously, the phase that is destined to form the electron acceptor structure can optionally contain one or more components such as amorphous carbon, graphite, cage molecules comprising carbon, such as fullerenes, and one or more catalysts, such as nickel, yttrium, cobalt, calcium, iron, platinum or palladium, which in particular are residues of the nanotube synthesis reaction.

The nanostructures also make it possible to improve dissipation of the heat originating from exposure of the cell to a light source, by virtue of their thermal conductivity. The nanostructures employed are in the form of fibrils having a high form factor and a typical minimum dimension of less than 200 nanometers. In particular, these geometric characteristics create a large interfacial area between the conjugated polymer and the nanostructures, making it possible to solve the technical problems referred to above.

Advantageously, the typical diameter of the tubular nanostructures is in the nanometer range and preferably between 0.5 and 200 nanometers, the preferred nanostructures being carbon nanotubes, especially Single-wall carbon nanotubes with a form factor of more than 150 and multi-wall carbon nanotubes with a preferred form factor of more than 5.

The form factor is defined as the ratio of the typical length to the typical diameter of the structure. The nanostructures described are tubular, can be hollow or solid and essentially consist of carbon atoms.

The typical diameter of the Single-wall nanotubes is generally between about 0.4 and 4 nanometers. The typical diameter of the multi-wall nanotubes is generally between about 1.4 and at least 100 nanometers. Their length is typically several hundred nanometers, but can be as much as several micrometers. The ends of the tubes can be open or closed by hemifulleroid structures.

Advantageously, the tubular nanostructures function as an electron acceptor structure when they are deposited on a substrate or mixed with a conjugated polymer.

The device of the present invention also needs an electron donor structure comprising conjugated polymers. “Conjugated polymers” are understood by the inventors as meaning any semiconducting polymers which have a system of delocalized π electrons. The following is a non-limiting list of suitable polymers:

polyacetylenes, polyparaphenylenes, polypyrrole sulfides, polyparaphenylene sulfides, polythiophenes, polyphenylene vinylenes, poly-3-methylthiophene, polycarbazole, polyisothianaphthene, poly(1,6-heptadiyne), poly-3-alkylthiophene in which the chosen alkyl is especially C₁-C₅, poly(3,4-ethylenedioxythiophene) or PEDOT, polyquinoline, poly-3-alkylsulfonate in which the chosen alkyl group is especially C₁-C₅, and polyaniline and derivatives thereof. The preferred polymers belong to the polyphenylene vinylene (PPV) and poly(3-octylthiophene) families.

However, the invention is not limited to these conjugated polymers and can be carried out using other conjugated polymers. In particular, the electron donor structure can be a pure conjugated polymer, a mixture of several conjugated polymers or a copolymer of a conjugated polymer.

The interfacial area between the electron acceptor structure and the electron donor structure must be as large as possible in order to maximize the number of dissociation sites.

Advantageously, the device of the present invention forms a PN heterojunction.

Advantageously, this device, which consists of contact between the nanostructures described and the conjugated polymer, forms the central and essential part of the photovoltaic cell.

According to a second feature, the invention relates to a process for the manufacture of a device comprising at least one type of conjugated polymer (forming an electron donor structure) and nanostructures. This process comprises the formation of an electron acceptor structure containing at least one type of tubular nanostructure selected from those described above.

Advantageously, the nanotubes are formed by techniques involving electrical discharge between carbon electrodes [D. S. Bethune, C. H. Kiang, M. S. De Vries, G. Gorman, R. Savoy, Nature 363, 605 (1993), and C. Journet, W. K. Maser, P. Bernier, A. Loiseau, M. Lamy de la Chapelle, S. Lefrant, P. Deniard, R. Lee, J. E. Fisher, Nature 388, 756 (1997)], laser ablation or chemical vapor phase deposition (CVD), as described in the following publications: M. J. Yacaman, M. M. Yoshida, L. Rendon, J. G. Santesban, Appl. Phys. Lett. 62, 202 (1993), or H. Dai, A. G. Rinzler, P. Nikolaev, A. Thess, D. T. Colbert, R. E. Smalley, Chem. Phys. Lett. 260, 471 (1996), or techniques involving carbon monoxide disproportionation [WO 0026138A1: Gas-phase nucleation and growth of single-wall carbon nanotubes from high-pressure CO], or any other similar technique.

Advantageously, the electron donor structure comprising the conjugated polymer is formed by a technique selected from the group consisting of the techniques involving shaping after melting of the polymer (such as hot extrusion, hot pressing), shaping from a solution (such as coating), free radical or anionic polymerization or electropolymerization, and any other similar technique.

In a first embodiment, the device is formed of at least on electron acceptor structure and an electron donor structure which are mutually discernible. In particular, the device is formed of an electron donor layer in contact with an electron acceptor layer.

Advantageously, the electron acceptor structure comprising the tubular nanostructure is assembled in the form of a “paper” or mat of nanotubes by deposition from a suspension containing the tubular nanostructures described above. This suspension of nanotubes containing adsorbed pigments can be obtained as described above. The deposition can be effected e.g. by frontal filtration of the suspension of complexed tubular nanostructures in the solvent. The solid part remaining on the filter forms a kind of self-supported paper typically a few tens of micrometers thick and mainly composed of complexed tubular nanostructures. The residual solvent can be evaporated off if necessary. The formulation of the solution of nanotubes complexed by pigments also contains a binding polymer. The binding polymer serves to cause pigment and solvent to interact and create a suspension. The arrangement of the tubular nanostructures in the mat of nanotubes is then random in the plane, conferring a planar anisotropy.

The binder is generally a block copolymer such as described above.

Advantageously, the electron acceptor structure comprising tubular nanostructures assembled in the form of a “paper” or mat of nanotubes, which will subsequently be brought into contact with the electron donor structure containing the conjugated polymer in particular, undergoes a treatment to increase the contact area with the electron donor structure.

Advantageously, the contact area is increased by any method that enables the nanostructures to leave the plane, for example by removing the binding polymer over a fraction of the thickness of the conducting layer in order to allow the nanostructures to emerge, it being possible for this operation to be effected by a chemical attack, a photon attack, such as laser or UV, a particle attack, such as electron or ion bombardment, or a mechanical attach, such as abrasion, or by a combination of such attacks.

Advantageously, a self-supported layer of paper of tubular nanostructures can be used directly as an electrode in a photovoltaic cell.

Advantageously, a layer of metal, preferably aluminum or gold, can be evaporated onto the self-supported layer of paper of tubular nanostructures in order further to decrease the contact resistance between the electron collector electrode and the external circuit.

Advantageously, the electron donor structure is deposited from a solution of conjugated polymer(s) or from molten conjugated polymer(s), or is formed by polymerization or electropolymerization based on the total or partial impregnation of the layer of nanostructures with a precursor monomer, or from any other similar preparation. The preferred conjugated polymers in this last case are polyaniline and polypyrrole.

Advantageously, this electron donor structure is deposited by injection, spin coating or a continuous roll-to-roll production process. The conjugated polymer can partially or totally impregnate the layer of nanostructures.

In general, the electron donor structure forming a layer comprising at least one conjugated polymer must have a thickness that enables the electromagnetic waves to reach the dissociation sites.

Preferably, the electron donor layer has a thickness of about 200 nm.

Preferably, the electron acceptor layer has a thickness of about 150 nm.

In a second advantageous embodiment the device is a composite structure formed by dispersing tubular nanostructures in the conjugated polymer.

In this embodiment the nanostructures dispersed in the conjugated polymer preferably form an electron conduction network for directing the electrons from the dissociation sites to the cathode. The electrons can creep over this network via the nanostructures and by hopping between them.

Advantageously, by virtue of their considerable length, the tubular nanostructures enable the electrons to be directed towards the cathode while minimizing, or even reducing to zero, the number of hops between nanostructures, which is the mode of conduction that limits the efficacy of electron transport. The electron conduction network then constitutes the electron acceptor structure.

Advantageously, the composite structure is produced by mixing, in solution, a previously prepared dispersion of said nanostructures complexed by pigments, as described above, with the conjugated polymer in an organic solution (by the process described above). The dispersion of nanostructures in the conjugated polymer, in the dry state, can be homogeneous or follow a gradient. A concentration gradient of nanostructures can be obtained e.g. by a sedimentation effect during a coating process.

In this embodiment, for the purpose of manufacturing a photovoltaic cell, it is advantageous to insulate the transparent electrode from the composite structure with a layer of conjugated polymer that does not contain nanostructures of the invention. In fact, without this insulation, nanostructures are frequently in direct contact with the conducting electrode, creating a short circuit between the two electrodes.

In general, the composite structure forming a layer comprising at least one conjugated polymer must have a thickness that enables the electromagnetic waves to reach the dissociation sites.

Preferably, the composite structure has a thickness of between about 300 and 500 nm.

Advantageously, this layer is deposited by injection, spin coating, a continuous roll-to-roll production process or any other similar method.

According to a third feature, the invention relates to a photovoltaic cell comprising a device as defined above.

According to a fourth feature, the invention relates to a photovoltaic cell comprising a device formed by a manufacturing process as defined above.

According to a fifth feature, the invention relates to a method of producing electricity from an electromagnetic wave, comprising:

a) the use of a device as defined above for effecting a photovoltaic conversion.

According to a sixth feature, the present invention relates to a method of producing electricity from an electromagnetic wave, comprising:

a) the bringing of a photovoltaic cell as defined above into contact with an electromagnetic wave emitted especially by the sun, and b) the generation of electricity from said photovoltaic cell, the photovoltaic cell being formed by any technique known to those skilled in the art.

Illustration of the Use of the Nanotubes of the Present Invention for Photovoltaic Conversion:

FIG. 5 shows the section of a standard photovoltaic cell with its different layers, including an electron acceptor layer based on a mat of nanotubes.

FIG. 6 shows a diagrammatic structure of the section of a photovoltaic cell containing a composite electron acceptor layer based on nanotubes.

FIG. 5 illustrates a section of a standard photovoltaic cell.

The photovoltaic cell (1A) comprises an electron donor layer (10) and an electron acceptor layer (20). The electron donor structure is formed especially of a conjugated polymer, as described in the present invention, or a mixture of conjugated polymers.

In the invention presented, the electron acceptor layer (20) is formed especially of at least one type of tubular nanostructure (22), as described in the present invention, i.e. complexed on its surface by at least one pigment (illustrated in FIG. 1).

After synthesis of the carbon nanotubes, for example by the known methods involving an electric arc, laser ablation or chemical vapor phase deposition, the electron acceptor entities are formed by complexing pigments with the nanotubes. The complexation can be carried out by an advantageous method of intimate mechanical mixing, after which the resulting nanostructures can be dissolved as described above. A binder (21) is added to this solution. A solution of suspended tubular nanostructures is then deposited on the electrode (30) by a method selected from spin coating, ink-jet printing and/or a continuous roll-to-roll production process. The layer (20) thus contains the tubular nanostructures mixed with a binder (21). The layer (10) is either deposited from a solution of conjugated polymers, or from molten conjugated polymers, or from any other similar preparation, or produced by the partial or total impregnation of the layer of tubular nanostructures with conjugated polymers so as to coat the whole of the electron acceptor part (20).

The electron donor structure (10) and electron acceptor structure (20) together form a PN heterojunction.

The electron acceptor structure (20) is in contact with the electrically conducting electrode (30), which is generally opaque and made of metal (aluminum, etc.).

The electron donor structure (10) is in contact with a transparent, electrically conducting electrode (40). Normally, the light that allows the photovoltaic cell to operate is directed towards the transparent electrode (40).

FIG. 6 diagrammatically shows a section of a photovoltaic cell (1B). This structure is identical to that of FIG. 5, except for the fact that the electron acceptor layer and the electron donor structure form a single, composite layer. This composite layer is formed of tubular nanostructures (122), as described in FIG. 1, which form an electron conduction network in the conjugated polymer matrix (110). This electron acceptor structure (120) is in contact with an electrically conducting electrode (130). This structure (120) is also in contact with an electron donor structure (150) formed essentially of a single conjugated polymer or a mixture of conjugated polymers. This layer of conjugated polymer(s) makes it possible to avoid a short circuit between the electrode (130) and the transparent conducting electrode (140). Such an embodiment makes it possible to use tubular nanostructures with a high form factor, which in particular allows direct transport of the electrons from the exciton dissociation site to the electrode (130). Also, the use of these tubular nanostructures allows ballistic transport of the electrons. This composite structure (120) can be formed in various ways. In particular, the nanostructures can be randomly dispersed, or orientated in the case of the application of a mechanical shear force or an electric or magnetic field.

Random dispersion of the tubular nanostructures is effected by mixing them in solution with the conjugated polymer, or from molten conjugated polymer, or by polymerization or electropolymerization of the conjugated polymer, or by any other similar technique. The dispersion of tubular nanostructures in the conjugated polymer can be homogeneous or follow a gradient. For example, a concentration gradient can be obtained by sedimentation of the “largest”, heaviest tubular structures, the gravitational force then taking precedence over the electrostatic-type interactions.

Other objects, characteristics and advantages of the invention will become clearly apparent to those skilled in the art from the explanatory description referring to Examples, which are given solely by way of illustration and cannot in any way limit the scope of the invention.

The Examples below form an integral part of the present invention and other characteristics that appear novel relative to any prior art on the basis of the description taken in its entirety, including the Examples, form an integral part of the invention in its function and in its general applicability.

Each Example thus has a general scope.

### Examples of Uses of the Nanotubes of the Present Invention for Photovoltaic Conversion

In Examples 16 to 21, the conjugated polymer can be polyaniline or polyparaphenylene vinylene.

### EXAMPLE 16

### Formation of an Electron Acceptor Structure in the Form of a Mat of Nanotubes From Tubular Nanostructures According to the Invention

The electron acceptor structures are formed using the electric arc method. Two graphite electrodes are placed face-to-face in an enclosure that has previously been evacuated and then filled with an inert gas. The anode consists of a graphite rod containing metal catalysts (nickel, yttrium or other mixture of rare earths), which is translationally mobile and supported by a conducting assembly; the cathode is a mobile graphite block cooled with water.

Once the system has been placed under tension, the anode is brought sufficiently close to the cathode to be able to generate an arc when current passes. The anode is subsequently kept at a distance in the order of a few millimeters. The energy dissipated by the Joule effect in the anode heats the rod until the graphite sublimes. The formation of the arc is accompanied by the creation of a plasma whose temperature can reach 6000 K. During the synthesis, the anode is continuously translated in the direction of the cathode as erosion progresses, so as to keep a constant distance between the electrodes.

Single-wall nanotubes are produced in conventional manner in a helium or argon enclosure under a negative pressure of about 5.10⁴ Pa, with a voltage in the order of 30 V and an intensity close to 100 A.

These nanostructures are then coated with pigments by the process described in Examples 1 to 15 of the present invention.

The electron acceptor structure is then assembled in the form of a “paper” or mat of nanotubes from a suspension of complexed nanotubes. This paper is obtained e.g. by frontal filtration of the suspension. This leads to the formation, on the filter, of a layer of nanostructures whose thickness can be controlled by the amount and concentration of the suspension employed. This step can optionally be followed by a rinsing step. A self-supported “paper” can then be removed from the filter and dried. NB: During filtration, the suspension of nanostructures can advantageously be kept homogeneous by agitating the solution.

### EXAMPLE 17

### Formation of an Electron Acceptor Structure From Tubular Nanostructures According to the Invention Optionally Comprising a Binder

An electron acceptor structure can be formed from a suspension of complexed Single-wall carbon nanotubes comprising a binder, such as those mentioned in Examples 1 to 15. In this case the electron acceptor structure can advantageously be deposited on a support, such as a conducting electrode when producing a photovoltaic cell, by spin coating. This step is followed by a drying step to drive off the residual solvent. The spin coating and drying operation can optionally be repeated any desired number of times. Advantageously, the use of a binding polymer makes it possible to stabilize the suspension of complexed Single-wall carbon nanotubes and increase its viscosity, extending the range of possible ways of producing the structure by the spin coating method.

The weight ratio nanostructures/binding polymer can exceed 1.

### EXAMPLE 18

### Formation of an Electron Acceptor Structure Based on Treated Carbon Nanotubes

The carbon nanotubes can be doped with boron to increase their electrical conductivity. For example, this doping can be effected by partial substitution on the Single-wall nanotubes with B₂O₃ (gas) under a nitrogen atmosphere at 1500-1700 K, as described in B. Goldberg et al., Carbon 38 (2000) 2017.

Alternatively, or in addition, the carbon nanotubes can be treated to increase their electronegativity by the halogenation and oxidation methods described in L. Duclaux, Carbon 40 (2002) 1751, including references.

The nanotubes are then complexed with a pigment as described in Examples 1 to 15.

The procedures for forming a paper of nanotubes (Example 16) and films of nanotubes comprising a binder (Example 17) can then be followed.

### EXAMPLE 19

### Formation of an Electron Acceptor Structure Based on Grafted Carbon Nanotubes

Treatments such as those described in U.S. patent 2002/004028 A1 or in the publication Chem. Mater. 14 (2002) 1472-1476, make it possible to increase the. electrophilic character of the nanotubes by grafting nucleophiles onto their surface.

The nanotubes are then complexed with a pigment as described in Examples 1 to 15.

The procedures for forming a paper of nanotubes (Example 16) and films of nanotubes comprising a binder (Example 17) can then be followed.

### EXAMPLE 20

### Formation of a PN Heterojunction Containing Two Distinct Layers

The electron acceptor structure described in Example 1 is coated with a layer of conjugated polymer from a solution of this polymer by the spin coating technique. Preferably, the layer of conjugated polymer is less than 100 nm. A semitransparent layer of aluminum (less than 100 nanometers) is then deposited by evaporation on the face opposite the electron acceptor structure in order to form an electrode. The other electrode can be formed directly by the self-supported paper of nanotubes or by any electronically conducting transfer thereon.

Alternatively, the electron acceptor structure described in Example 17 is prepared on a conducting substrate of indium tin oxide (ITO). Advantageously, the binding polymer is at least superficially degraded by a heat treatment (heating under vacuum at high temperature). A thin layer (preferably less than 100 nm) of conjugated polymer is then deposited on this device by spin coating from a solution of this conjugated polymer. A semitransparent layer of aluminum (less than 100 nanometers) is then deposited by evaporation on the face opposite the ITO in order to form the second electrode.

As another alternative, a thin layer (preferably less than 100 nm) of conjugated polymer is deposited on an ITO substrate by spin coating from a solution of this conjugated polymer. The electron acceptor structure is prepared on this device as described in Example 17. The device is then dried under vacuum in an oven, but at moderate temperature, in order to extract the solvent. A layer of aluminum a few hundred nanometers thick is then deposited by evaporation on the face opposite the ITO in order to form the other electrode.

### EXAMPLE 21

### Formation of a PN Heterojunction Having a Composite Layer

A thin layer (preferably less than 100 nm) of conjugated polymer is deposited on an ITO substrate by spin coating from a solution of this conjugated polymer. This preparation is left to stand for a few minutes at ambient temperature in a desiccator under nitrogen.

After having been intimately mixed mechanically with the pigment by the method described in Examples 1 to 15, the (Single-wall or multi-wall) carbon nanotubes are incorporated into and mixed with another solution of this same conjugated polymer. This preparation is deposited by spin coating on the previously obtained substrate. Particular care must be taken during this processing step in order to avoid any contamination by dust. The coating/drying operation can be repeated any desired number of times after drying for a few minutes under nitrogen. The device is then dried under vacuum in an oven, but at moderate temperature, in order to extract the solvent.

A layer of aluminum a few hundredths of nanometers thick is then deposited by evaporation on the face opposite the ITO in order to form the other electrode.

1. Device comprising an electron donor structure containing at least one type of conjugated polymer, and an electron acceptor structure containing at least one type of a tubular nanostructure having at least one complexed or adsorbed pigment on its surface.

2. Device according to claim 1, wherein the tubular nanostructure is selected from the group consisting of straight Single-wall carbon nanotubes, straight double-wall carbon nanotubes, straight multi-wall carbon nanotubes, bent Single-wall carbon nanotubes, bent double-wall carbon nanotubes, bent multi-wall carbon nanotubes (SWNT, DWNT and MWNT), and any mixture thereof.

3. Device according to claim 1, wherein the pigment complexed on the tubular nanostructure is selected from the group consisting of inorganic pigments treated so as to be compatible with a polymer or an organic solvent, azo pigments, yellow and orange monoazo pigments, diazo pigments, naphthol pigments, Naphthol® AS pigments (naphthol red), azo pigment lakes, benzimidazolone pigments, diazo condensation pigments, complex metal pigments, isoindolinone and isoindoline pigments, polycyclic pigments, phthalocyanine pigments, a sulfonated copper phthalocyanine containing an average of 0.5 to 3 sulfonic acid groups, a chlorinated copper phthalocyanine, an aluminum phthalocyanine, a brominated phthalocyanine, an aluminum phthalocyanine, a metal-free phthalocyanine, quinophthalone pigments, indathrone pigments, yellow diacrylide pigments, diazopyrazolone pigments, azo-metal pigments, triarylcarbonium pigments, rhodamine lake pigments, perylene pigments, quinacridone pigments and diketopyrrolopyrrole pigments, molecules of porphyrin or derivatives thereof, and mixtures of two or more of all these.

4. Device according to claim 1, wherein the typical diameter of the nanostructures is in the range between 0.5 and 200 nanometers.

5. Device according to claim 1, wherein the tubular nanostructure has a layer of at least one pigment directly adsorbed on its outer periphery, and at least one polymer having an anchoring point on said layer of at least one pigment.

6. Device according to claim 5, wherein the polymer having an anchoring point on said layer of at least one pigment is a hydroxyoctadecanoic acid/aziridine block copolymer.

7. Device according to claim 5, wherein the weight ratio nanotubes/pigment/polymer is between 1/1/1 and 1/5/1.

8. Device according to claim 1, wherein the pigment is phthalocyanine.

9. Device according to claim 1, wherein the conjugated polymer is selected from the group consisting of polyacetylenes, polyparaphenylenes, polypyrrole sulfides, polyparaphenylene sulfides, polythiophenes, polyphenylene vinylenes, poly-3-methylthiophene, polycarbazole, polyisothianaphthene, poly(1,6-heptadiyne), poly-3-alkylthiophene in which the chosen alkyl is especially C₁-C₅, poly(3,4-ethylenedioxythiophene) or PEDOT, polyquinoline, poly-3-alkylsulfonate in which the chosen alkyl group is especially C₁-C₅, and polyaniline and derivatives thereof, preferably polyphenylene vinylenes and poly(3-octylthiophenes).

10. Device according to claim 1, wherein the tubular nanostructure functions as an electron acceptor structure mixed with a binding polymer.

11. Device according to claim 1 wherein the electron acceptor structure and electron donor structure are mutually discernible or form a composite structure.

12. Device according to claim 1, wherein said device forms a PN heterojunction of a photovoltaic cell.

13. Process for the manufacture of a device as defined in claim 1 containing at least one type of conjugated polymer, wherein said process comprises a step for forming a structure functioning as an electron acceptor structure which comprises at least one type of tubular nanostructure, which in turn comprises at least one complexed or adsorbed pigment on its surface.

14. Manufacturing process according to claim 13, wherein the tubular nanostructures are assembled in the form of a paper or mat of nanotubes by deposition from a suspension containing tubular nanostructures.

15. Manufacturing process according to claim 13, wherein the tubular nanostructures assembled in the form of a paper undergo a treatment to increase the contact area with the electron donor structure.

16. Manufacturing process according to claim 13, wherein the electron donor structure is deposited from a solution of conjugated polymer or from molten conjugated polymer by injection or spin coating.

17. Manufacturing process according to claim 13, wherein the device comprises a composite structure forming the electron acceptor structure and the electron donor structure, said composite structure being produced by mixing, in solution, tubular nanostructures with the conjugated polymer, or by a molten method.

18. Photovoltaic cell comprising a device as defined in claim 1.

19. Method of producing electricity from an electromagnetic wave, wherein said method comprises:
a) the use of a device as defined in claim 1 for effecting a photovoltaic conversion.

20. Method of producing electricity from an electromagnetic wave, wherein said method comprises:
a) the bringing of a photovoltaic cell as defined in claim 18 into contact with an electromagnetic wave emitted especially by the sun, and
b) the generation of electricity from said photovoltaic cell.
